(19) United States
(12) Patent Application Publication
(10) Pub. No.: US 2023/0231359 A1
(43) Pub. Date: Jul. 20, 2023

(54) MULTI-WAVELENGTH LASER AND ROUTER WITH FAST SWITCHABLE OUTPUT PORTS AND WAVELENGTHS

(71) Applicant: Hangzhou Lightip Technologies Co., Ltd., Hangzhou (CN)

(72) Inventors: Jiasheng ZHAO, Hangzhou (CN); Jia GUO, Hangzhou (CN); Jian-jun HE, Hangzhou (CN)

(21) Appl. No.: 18/185,420

(22) Filed: Mar. 17, 2023

(30) Foreign Application Priority Data
Mar. 21, 2022 (CN) 202210277817.8

(51) Int. Cl. H01S 5/026; H01S 5/40; H01S 5/14

(52) U.S. Cl. CPC H01S 5/0268; H01S 5/4087; H01S 5/141

(57) ABSTRACT

A multi-wavelength multi-port laser and router. By arranging a reflective facet at one end of the port-selection semiconductor optical amplifier and a partial reflector at one end of the wavelength-selection semiconductor optical amplifier, and cooperating with the intra-cavity wavelength router to form N×N optical resonant cavities, so that each optical resonant cavity can only emit the wavelength corresponding to the lowest round-trip loss between input and output ports. The extra-cavity wavelength router is mirrored with respect to the intra-cavity wavelength router, so that one or more wavelengths of light excited by any port-selection semiconductor optical amplifier can be transmitted from the corresponding output port of the extra-cavity wavelength router. The switching of the wavelength and output ports of the router is performed by on-off switching of the port-selection semiconductor optical amplifier and wavelength-selection semiconductor optical amplifier, and the switching time can be less than 1 ns.

### CROSS-REFERENCE TO RELATED APPLICATIONS

This application claims the benefit of priority from Chinese Patent Application No. 202210277817.8, filed on Mar. 21, 2022. The content of the aforementioned application, including any intervening amendments thereto, is incorporated herein by reference in its entirety.

### TECHNICAL FIELD

The invention relates to a multi-wavelength and multi-port laser and optical transmission router, which can be rapidly switched between output ports and wavelengths. It is suitable for the technical field of semiconductor optical transmitters and routers.

### BACKGROUND

The rapid growth of data center network traffic requires more efficient interconnection methods. Currently, a variety of all-optical interconnection network architectures have been proposed based on tunable lasers, passive wavelength routers, and optical switches, with high bandwidth, low cost, and low power consumption, and low latency.

In the prior art, a distributed optical switching network architecture has been proposed based on a tunable laser transmitter and a cyclic wavelength router, which places a cyclic wavelength router at each transmitting/receiving node as a multiplexer/de-multiplexer/router. Direct connection between different nodes can be achieved without the need for optical-electrical-optical conversion. Each link can use N wavelengths for simultaneous transmission, so that the bandwidth of the link between any two nodes is N times the bandwidth of a single channel. The switching speed of this optical switching technology depends on the switching speed of the tunable laser. The switching speed of the chip using the carrier plasma effect can be less than 10 ns, while the switching speed of the chip based on current injection induced thermo-optic effect is about 20-100 μs.

Microsoft introduced another flat optical switching data center network called Sirius at SIGCOMM 2020 under the title “Sirius: A flat datacenter network with nanosecond optical switching.” Lasers and cyclic arrayed waveguide grating routers enable sub-nanosecond latency optical interconnection. However, only one wavelength is transmitted between any two nodes, and its bandwidth is limited to one wavelength channel. Moreover, the switching of each channel requires multi-electrode control, which makes the system more complex, and requires sophisticated algorithms for scheduling, synchronization, and control.

### SUMMARY

To solve the above-mentioned problems, the present invention provides a multi-wavelength multi-port laser and optical transmission router whose output ports and wavelengths can be rapidly switched.

The technical scheme adopted by the present invention is: a multi-wavelength multi-port laser whose output ports and wavelengths can be switched rapidly, characterized in that it comprises:

a N×N intra-cavity wavelength router, in which the transmission from any one of the input ports to any one of the output ports has the smallest loss only at a specific wavelength;

N port-selection semiconductor optical amplifiers, with one-to-one correspondence with the input ports of the N×N intra-cavity wavelength router, one end of each port-selection semiconductor optical amplifier is terminated by a highly reflective or partially reflective facet, and the other end is connected to an input port of the intra-cavity wavelength router;

N wavelength-selection semiconductor optical amplifiers, with one-to-one correspondence with the output ports of the N×N intra-cavity wavelength router, one end of each of the wavelength-selection semiconductor optical amplifier is connected to an output port of the intra-cavity wavelength router, and the other end is provided with a partial reflector.

An optical resonant cavity of a certain wavelength is formed between the reflective facet of any one of the port-selection semiconductor optical amplifiers and the partial reflector of any one of the wavelength-selection semiconductor optical amplifiers.

By applying currents to the port-selection semiconductor optical amplifier and the wavelength-selection semiconductor optical amplifier corresponding to any pair of input and output port combinations of the intra-cavity wavelength router, a laser emission with the specific lowest-loss wavelength corresponding to the input and output port combination of the intra-cavity wavelength router is transmitted through the partial reflector of the corresponding optical resonant cavity.

The intra-cavity wavelength router is a cyclic wavelength router, in which the designed channel spacing between the N wavelength channels is 1/N of the entire free spectral range of the wavelength router.

The intra-cavity wavelength router is an etched diffraction grating router.

The intra-cavity wavelength router is an arrayed waveguide grating router.

A multi-wavelength multi-port optical transmission router with fast switchable output ports and wavelengths, comprising:

the multi-wavelength multi-port laser;

N modulators, connected to the output ports of the multi-wavelength multi-port laser in one-to-one correspondence, which are used for modulating the laser outputs of the multi-wavelength multi-port laser;

an extra-cavity wavelength router, whose input ports are connected to the N modulators in a one-to-one correspondence, for routing the laser of a specific wavelength after modulation by the modulator to the corresponding output port of the extra-cavity wavelength router based on the input port and the wavelength.

The extra-cavity wavelength router has the same structure as the intra-cavity wavelength router in the multi-wavelength multi-port laser, and is disposed in mirror image with respect to the intra-cavity wavelength router, whereas the input ports of the extra-cavity wavelength router correspond to the output ports of the intra-cavity wavelength router.

The multi-wavelength multi-port optical transmission router may further comprise N signal gain semiconductor optical amplifiers, which are connected with the output ports of the extra-cavity wavelength router in one-to-one correspondence.

The output ends of the signal gain semiconductor optical amplifiers are coated with an anti-reflection film.

By applying currents to a certain port-selection semiconductor optical amplifier and one or more wavelength-selection semiconductor optical amplifiers, the multi-wavelength laser outputs one or more specific wavelengths corresponding to the combination of the input and output ports in the intra-cavity wavelength router.

After one or more laser beams with specific wavelengths output by the multi-wavelength laser are modulated by the modulators, the extra-cavity wavelength router routes them to the output port of the extra-cavity wavelength router corresponding to the certain port-selection semiconductor optical amplifier of the intra-cavity wavelength router.

The output of the corresponding output port of the extra-cavity wavelength router includes one or more modulated laser signals with specific wavelengths, which are amplified by the signal gain semiconductor optical amplifier.

The beneficial effects of the present invention are as follows: the present invention provides a reflection facet at one end of the port-selection semiconductor optical amplifier, and a partial reflector at one end of the wavelength-selection semiconductor optical amplifier, and cooperates with the intra-cavity wavelength router to form N×N optical resonant cavities. Since any combination of input and output ports of the intra-cavity wavelength router only has the smallest loss at a specific wavelength, each optical resonator can only emit laser light with the wavelength corresponding to the input and output port combination. One only needs to turn on a port-selection semiconductor optical amplifier and one or more wavelength-selection semiconductor optical amplifiers, the laser emissions of the specified wavelengths can be quickly transmitted at the corresponding output port of the extra-cavity wavelength router.

The multi-wavelength multi-port laser and optical transmission router of the present invention can transmit multiple laser signals of different wavelengths simultaneously by applying currents to any port-selection semiconductor optical amplifier and multiple wavelength-selection semiconductor optical amplifiers.

In this invention, the specific wavelength laser output from the multi-wavelength laser is modulated by the modulator, and routed to the specified output port of the extra-cavity wavelength router based on the input port and wavelength of the laser through the extra-cavity wavelength router, and the multi-wavelength signals received by the multiple input ports can be multiplexed and routed to the same output port.

The extra-cavity wavelength router in the present invention has the same structure as the intra-cavity wavelength router in the multi-wavelength multi-port laser, and is disposed in a mirror image with respect to the intra-cavity wavelength router. This allows one or more wavelengths of light excited by any port-selection semiconductor optical amplifier can be transmitted from the output port of the extra-cavity wavelength router corresponding to the port-selection semiconductor optical amplifier.

In the present invention, the switching of the wavelength and the port of the router is realized by the on-off switching of the semiconductor optical amplifiers, and the switching speed is determined by the response time of the semiconductor optical amplifier. Taking the port-selection semiconductor optical amplifier as an example, the switching time of its turn-on and turn-off can be less than 1 ns.

### BRIEF DESCRIPTION OF THE DRAWINGS

FIG. 1 is a schematic structural diagram of an embodiment of the present invention.

FIG. 2 is explanatory optical loss spectra illustrating the wavelength selection principle of the wavelength router in the embodiment.

FIG. 3 is an explanatory diagram of the wavelength and port switching principle of the embodiment.

FIG. 4 is a schematic structural diagram of an etched diffraction grating wavelength router.

FIG. 5 is a schematic structural diagram of an arrayed waveguide grating wavelength router.

FIG. 6 is a schematic design of an embodiment using an etched diffraction grating router.

FIG. 7 is a superimposed output spectra measured after the first port-selection semiconductor optical amplifier and different wavelength-selection semiconductor optical amplifiers are tuned-on in the embodiment.

FIG. 8 is a superimposed output spectra measured after the third port-selection semiconductor optical amplifier and different wavelength-selection semiconductor optical amplifiers are tuned-on in the embodiment.

FIG. 9 is a multi-wavelength output spectrum measured after the third port-selection semiconductor optical amplifier and multiple wavelength-selection semiconductor optical amplifiers are tuned-on in the embodiment.

FIG. 10 is an exemplary response of the turn-on and turn-off of a port-selection semiconductor optical amplifier in the embodiment.

In the drawings: 1. port-selection semiconductor optical amplifier; 2. intra-cavity wavelength router; 3. wavelength-selection semiconductor optical amplifier; 4. modulator; 5. extra-cavity wavelength router; 6. signal gain semiconductor optical amplifier; 7. input port of wavelength router; 8. etched diffraction grating; 9. output port of wavelength router; 10. star coupler; and 11. arrayed waveguide grating.

### DETAILED DESCRIPTION OF EMBODIMENTS

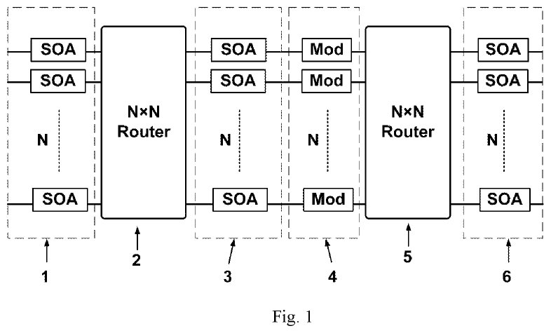

As shown in FIG. 1, this embodiment provides a multi-wavelength and multi-port optical transmission router whose output port and wavelength can be rapidly switched, which is composed of an intra-cavity router and an extra-cavity router.

In this example, the multi-wavelength multi-port laser comprises an N×N intra-cavity wavelength router, N port-selection semiconductor optical amplifiers and N wavelength-selection semiconductor optical amplifiers. Any combination of input and output ports of the intra-cavity wavelength router only has the smallest loss at a specific wavelength.

In this embodiment, the N port-selection semiconductor optical amplifiers are connected to the N input ports of the intra-cavity wavelength router in one-to-one correspondence. One end of the port-selection semiconductor optical amplifier is a reflective facet coated with a high-reflection film, and the other end is connected to one input port of the intra-cavity wavelength router.

The N wavelength-selection semiconductor optical amplifiers are connected to the N output ports of the intra-cavity wavelength router in one-to-one correspondence. One end of the wavelength-selection semiconductor optical amplifier is connected to one output port of the intra-cavity wavelength router, and the other end is provided with a partial reflector.

In this embodiment, any port-selection semiconductor optical amplifier and any wavelength-selection semiconductor optical amplifier cooperate with the intra-cavity wavelength router to form an optical resonant cavity.

By operating any port-selection semiconductor optical amplifier and multiple wavelength-selection semiconductor optical amplifiers at the same time, lasers of corresponding wavelengths can be combined from the multiple wavelength-selection semiconductor optical amplifiers and the corresponding input and output ports of the intra-cavity wavelength router. In this example, switching different wavelength-selection semiconductor optical amplifiers can switch the output wavelength.

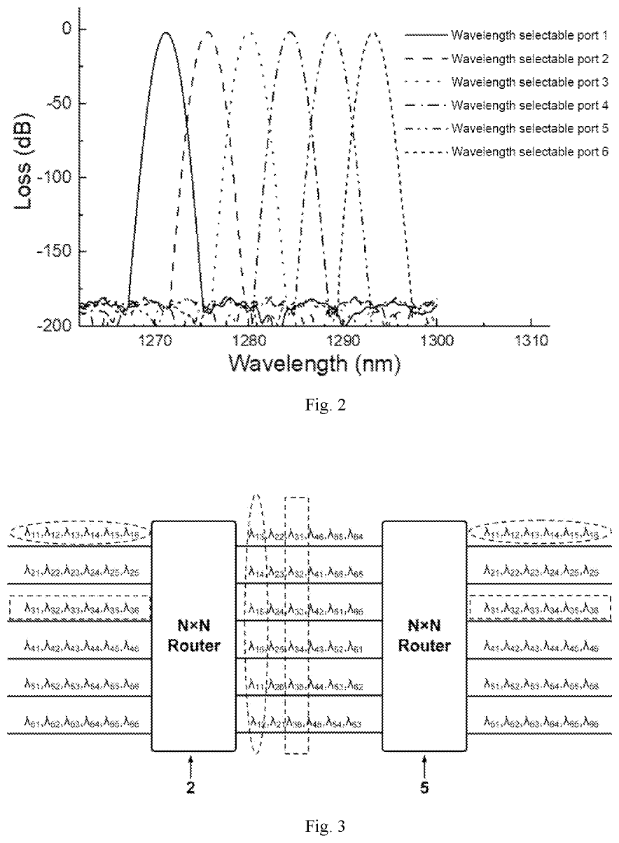

Taking a six-channel intra-cavity laser as an example. FIG. 2 shows the loss spectrum of the light passing through the intracavity wavelength router with different wavelength-selection semiconductor optical amplifier tuned on together with the third port-selection semiconductor optical amplifier. It can be seen that after selecting the port-selection semiconductor optical amplifier, different wavelengths can be selected by tuning on the corresponding wavelength-selection semiconductor optical amplifier, and the wavelength is automatically aligned with the lowest-loss wavelength of the intra-cavity wavelength router. Multiple wavelength-selection semiconductor optical amplifiers can be turned on at the same time to realize simultaneous transmission of multiple wavelengths.

In this embodiment, the extra-cavity components include N modulators, an N×N extra-cavity wavelength router, and N signal gain semiconductor optical amplifiers. The N×N extra-cavity wavelength router has the same structure as the intra-cavity wavelength router in the multi-wavelength multi-port laser, and are mirrored with the intracavity wavelength router. The input ends of the extra-cavity wavelength router correspond one-to-one with the output ends of the intra-cavity wavelength router, and the output ends of the extra-cavity wavelength router correspond one-to-one with the input ends of the intra-cavity wavelength router.

In this embodiment, the N modulators are connected to the N partial reflectors of the intracavity laser in a one-to-one correspondence, and are used to modulate the lasers of different wavelengths output by the intracavity laser. The N modulators are connected to the N input ends of the extra-cavity wavelength router in one-to-one correspondence, and the extra-cavity wavelength router routes the laser modulated by the modulators to the corresponding output ports of the extra-cavity wavelength router according to the input ports and wavelengths.

Since the extra-cavity wavelength router and the intra-cavity wavelength router in this embodiment have the same structure and are arranged in mirror images, the laser light of one or more wavelengths excited by the port-selection semiconductor optical amplifier on the input end of the intra-cavity wavelength router will be routed to the output port of the extra-cavity wavelength router corresponding to the selected input port of the intra-cavity wavelength router after passing through the extra-cavity wavelength router.

In this embodiment, the N signal gain semiconductor optical amplifiers are in one-to-one correspondence with the N output ends of the extra-cavity wavelength router. One end of the signal gain semiconductor optical amplifier is connected to an output end of the extra-cavity wavelength router, and the other end of the signal gain semiconductor optical amplifier is used as an output port of the multi-wavelength transmitting router. The signal gain semiconductor optical amplifier is used for amplifying the signal output by the extra-cavity wavelength router.

In this embodiment, in order to prevent the formation of extra resonance in the extra-cavity router, a high-transmission (anti-reflection) film is coated on the output facet of the signal gain semiconductor optical amplifier.

The wavelength and port switching principle of the multi-wavelength multi-port optical transmitting router is illustrated in FIG. 3. Taking the six-channel transmitting router as an example, when one port-selection semiconductor optical amplifier is tuned on together with each of the six wavelength-selection semiconductor optical amplifiers individually, it can excite the light of six wavelengths, respectively, after passing through the 6×6 intra-cavity wavelength router. Its wavelength is represented by λᵢⱼ, where i is the index for the port-selection semiconductor optical amplifier, and j is the index for the wavelength. As shown in FIG. 3, when the first input port is selected by turning on the corresponding port-selection semiconductor optical amplifier, the lasing wavelength is λ₁₁, λ₁₂, λ₁₃, λ₁₄, λ₁₅, and λ₁₆, respectively, when the 5th, 6th, 1st, 2nd, 3rd, and 4th wavelength-selection semiconductor optical amplifier is tuned on. After routing by the 6×6 extra-cavity wavelength router, since the two wavelength routers inside and outside the cavity are symmetrical, the light of these six wavelengths will be routed to the first signal gain semiconductor optical amplifier for output.

By turning on different wavelength-selection semiconductor optical amplifiers, different wavelengths will be emitted, and wavelength switching can be realized by switching the wavelength-selection semiconductor optical amplifiers.

Similarly, by tuning on the port-selection semiconductor optical amplifier at the third input port, and the lasing wavelength becomes λ₃₁, λ₃₂, λ₃₃, λ₃₄, λ₃₅, and λ₃₆, respectively, when the 1st, 2nd, 3rd, 4th, 5th, and 6th wavelength-selection semiconductor optical amplifiers are turned on. After routing by the 6×6 extra-cavity wavelength router, the light of these six wavelengths will be directed to the third signal gain semiconductor optical amplifier for output.

In this embodiment, all wavelengths excited by the i-th port-selection semiconductor optical amplifier will be routed to the output of the i-th gain semiconductor optical amplifier. In this way, the port switching function can be realized by switching on one of the port-selection semiconductor optical amplifiers together with the corresponding gain semiconductor optical amplifier.

In this embodiment, both the intra-cavity wavelength router and the extra-cavity wavelength router is preferably cyclic wavelength routers. That is, for an N×N wavelength router, the designed channel spacing of its N channels is 1/N of the entire free spectral range of the wavelength router. This can ensure that all wavelengths excited by any one port-selection semiconductor optical amplifier circulate among the same set of N wavelengths.

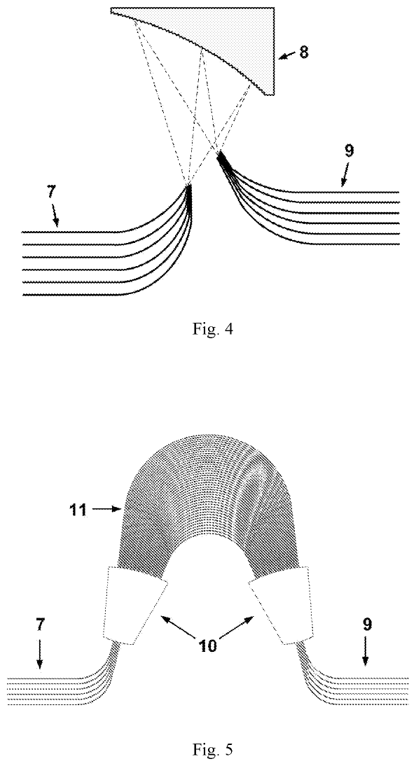

An implementation manner of the intra-cavity wavelength router and the extra-cavity wavelength router in this embodiment is an etching diffraction grating router. The schematic diagram of its structure is shown in FIG. 4. The wavelength router consists of an array of input ports, an etched diffraction grating and an array of output ports. The basic design of the etched diffraction grating router is based on the Roland circle theory. The grating is located on a large circle with a radius of R, and the input and output points are located on a small circle with a radius of R/2. Light of a specific wavelength incident from an input port is reflected by a plurality of tooth surfaces of the grating, and then diffracted and focused on an output port. This allows for minimal loss of light with only one wavelength of light for any pair of input and output ports.

Another implementation of the intra-cavity wavelength router and the extra-cavity wavelength router in this embodiment is an arrayed waveguide grating. The schematic diagram of its structure is shown in FIG. 5, which consists of an array of the input ports, two star couplers, an arrayed waveguide grating, and an array of output ports. Light of a specific wavelength incident from an input port is freely transmitted in the first star coupler and then enters the arrayed waveguide grating, which is composed of multiple waveguides with different lengths. The phase shifts of the light after passing through the arrayed waveguides are different, and the interference image is focused at a specific output port after passing through the second star coupler. This also achieves minimal loss of light with only one wavelength for any pair of input and output ports.

In this embodiment, the modulator can realize high-speed modulation of the optical signal. One implementation is an array of electro-absorption modulators, and the other is an array of Mach-Zehnder modulators.

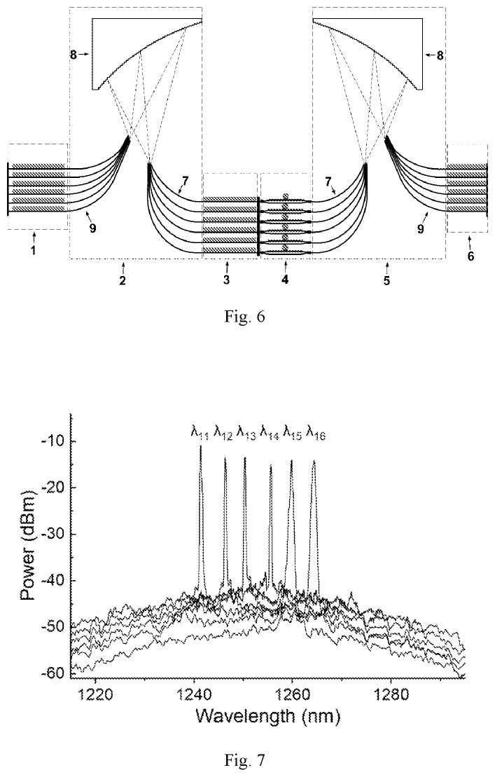

FIG. 6 is a schematic diagram of a specific design structure of an implementation manner of a multi-wavelength transmitting router in this embodiment. The intra-cavity wavelength router and the extra-cavity wavelength router are two symmetrically disposed cyclic etched diffraction gratings. The wavelength selection semiconductor optical amplifier and the modulator are connected through an on-chip partial reflector, which can be fabricated through a deep etching groove.

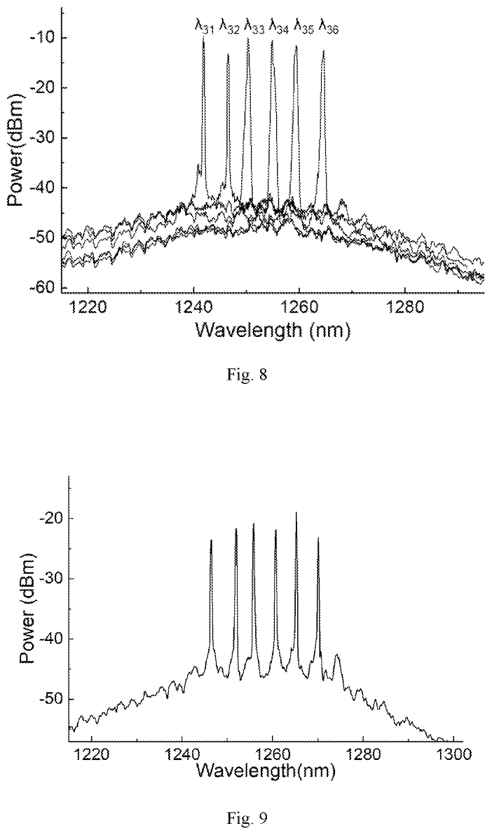

The exemplary device is fabricated according to the design method in FIG. 6. After selecting the first port by tuning on the first port-selection semiconductor optical amplifier, and selecting different wavelengths by tuning on the corresponding wavelength-selection semiconductor optical amplifiers, the measured single-wavelength output spectra are superimposed as shown in FIG. 7. After selecting the third port by tuning on the third port-selection semiconductor optical amplifier, and selecting different wavelengths by tuning on the corresponding wavelength-selection semiconductor optical amplifier, and the measured single-wavelength output spectra are superimposed as shown in FIG. 8. Each output port can achieve single-wavelength or multi-wavelength output, and the output wavelengths can be switched among the same six wavelengths.

In this embodiment, after the third port-selection semiconductor optical amplifier is selected, and when currents are applied to all wavelength-selection semiconductor optical amplifiers, the simultaneous multi-wavelength output spectrum is measured as shown in FIG. 9. Each port can achieve multi-wavelength output within the same set of six wavelengths in this exemplary device.

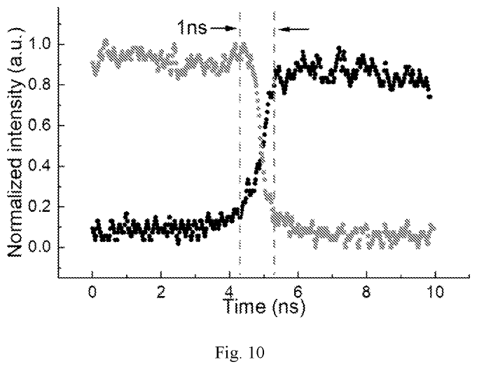

In this embodiment, the switching of the wavelength and the port of the multi-wavelength multi-port optical transmitting router is realized by the on-off switching of the semiconductor optical amplifiers, and the switching speed is determined by the response time of the semiconductor optical amplifier being turned on and off. Taking the third port-selection semiconductor optical amplifier as an example, its turn-on and turn-off response times are shown in FIG. 10, and the switching speed is less than 1 ns.

The operation method of the multi-wavelength multi-port optical transmitting router in this embodiment is as follows:

Determine the output port and wavelengths of the multi-wavelength transmitting router according to the signal transmission requirements;

According to the output port and the wavelengths, a corresponding port-selection semiconductor optical amplifier and one or more wavelength-selection semiconductor optical amplifiers are selected;

By applying currents to the corresponding port-selection semiconductor optical amplifier and the wavelength-selection semiconductor optical amplifiers, the multi-wavelength laser outputs laser signals at one or more specific wavelengths corresponding to the combination of the corresponding input and output ports on the intra-cavity wavelength router;

After the signals of one or more specific wavelengths are transmitted by the multi-wavelength multi-port laser and are modulated by the modulators, they are routed by the extra-cavity wavelength router to the output port corresponding to the port-selection semiconductor optical amplifier;

The output from the corresponding output port of the extra-cavity wavelength router includes one or more modulated laser signals with specific wavelengths, which are amplified by the signal gain semiconductor optical amplifier and then transmitted.

In this embodiment, the multi-wavelength multi-port optical transmission router can be integrated on the same substrate. The port-selection semiconductor optical amplifier array, the wavelength-selection semiconductor optical amplifier array and the signal gain semiconductor optical amplifier array are fabricated on active materials that can provide optical gain. The extra-cavity wavelength router and the intra-cavity wavelength router are fabricated on passive materials with lower optical loss, and the modulator array is fabricated on active materials that can realize high-speed electro-optic modulation.

One of the integration methods in this embodiment is InP-based monolithic integration. By means of quantum well intermixing, butt-coupling using etch-and-regrowth, and selective area epitaxy, different regions on the same substrate can have different bandgaps and material properties. Another integration approach is hybrid integration, where the region providing optical gain can be fabricated using InP-based quantum well materials. The area that provides wavelength routing can be fabricated using materials such as silicon-on-insulator (SOI), silicon nitride (Si₃N₄), silicon oxide (SiO₂), etc. The modulator array region can be fabricated using InP-based materials, doped SOI, and lithium niobate (LiNbO₃) and other materials, and then different devices can be integrated on the same substrate by means of heterogeneous integration.

What is claimed is:

1. A multi-wavelength multi-port laser with fast switchable output ports and wavelengths, comprising:
a N×N intra-cavity wavelength router, in which the transmission from any one of the input ports to any one of the output ports has the smallest loss only at a specific wavelength;
N port-selection semiconductor optical amplifiers, with one-to-one correspondence with the input ports of the N×N intra-cavity wavelength router, one end of each port-selection semiconductor optical amplifier is terminated by a highly reflective or partially reflective facet, and the other end is connected to an input port of the intra-cavity wavelength router;
N wavelength-selection semiconductor optical amplifiers, with one-to-one correspondence with the output ports of the N×N intra-cavity wavelength router, one end of each of the wavelength-selection semiconductor optical amplifier is connected to an output port of the intra-cavity wavelength router, and the other end is provided with a partial reflector;
whereas an optical resonant cavity of a certain wavelength is formed between the reflective facet of any one of the port-selection semiconductor optical amplifiers and the partial reflector of any one of the wavelength-selection semiconductor optical amplifiers.

2. The multi-wavelength multi-port laser of claim 1, wherein by applying currents to the port-selection semiconductor optical amplifier and the wavelength-selection semiconductor optical amplifier corresponding to any pair of input and output port combinations of the intra-cavity wavelength router, a laser emission with the specific lowest-loss wavelength corresponding to the input and output port combination of the intra-cavity wavelength router is transmitted through the partial reflector of the corresponding optical resonant cavity.

3. The multi-wavelength multi-port laser of claim 1, wherein the intra-cavity wavelength router is a cyclic wavelength router, in which the designed channel spacing between the N wavelength channels is 1/N of the entire free spectral range of the wavelength router.

4. The multi-wavelength multi-port laser of claim 2, wherein the intra-cavity wavelength router is a cyclic wavelength router, in which the designed channel spacing between the N wavelength channels is 1/N of the entire free spectral range of the wavelength router.

5. The multi-wavelength multi-port laser of claim 3, wherein the intra-cavity wavelength router is an etched diffraction grating router.

6. The multi-wavelength multi-port laser of claim 4, wherein the intra-cavity wavelength router is an etched diffraction grating router.

7. The multi-wavelength multi-port laser of claim 3, wherein the intra-cavity wavelength router is an arrayed waveguide grating router.

8. The multi-wavelength multi-port laser of claim 4, wherein the intra-cavity wavelength router is an arrayed waveguide grating router.

9. A multi-wavelength multi-port optical transmission router with fast switchable output ports and wavelengths, comprising:
the multi-wavelength multi-port laser of claim 1;
N modulators, connected to the output ports of the multi-wavelength multi-port laser in one-to-one correspondence, which are used for modulating the laser outputs of the multi-wavelength multi-port laser; and
an extra-cavity wavelength router, whose input ports are connected to the N modulators in a one-to-one correspondence, for routing the laser of a specific wavelength after modulation by the modulator to the corresponding output port of the extra-cavity wavelength router based on the input port and the wavelength.

10. The multi-wavelength multi-port optical transmission router of claim 9, wherein the extra-cavity wavelength router has the same structure as the intra-cavity wavelength router in the multi-wavelength multi-port laser, and is disposed in mirror image with respect to the intra-cavity wavelength router, whereas the input ports of the extra-cavity wavelength router correspond to the output ports of the intra-cavity wavelength router.

11. The multi-wavelength multi-port optical transmission router of claim 9, further comprising:
N signal gain semiconductor optical amplifiers, which are connected with the output ports of the extra-cavity wavelength router in one-to-one correspondence.

12. The multi-wavelength multi-port optical transmission router of claim 10, further comprising:
N signal gain semiconductor optical amplifiers, which are connected with the output ports of the extra-cavity wavelength router in one-to-one correspondence.

13. The multi-wavelength multi-port optical transmission router of claim 11, wherein the output end of the signal gain semiconductor optical amplifier is coated with a high transmission film.

14. The multi-wavelength multi-port optical transmission router of claim 12, wherein the output end of the signal gain semiconductor optical amplifier is coated with a high transmission film.

15. The multi-wavelength multi-port optical transmission router of claim 13, wherein by applying currents to a certain port-selection semiconductor optical amplifier and one or more wavelength-selection semiconductor optical amplifiers, the multi-wavelength laser outputs one or more specific wavelengths corresponding to the combination of the input and output ports in the intra-cavity wavelength router;
after one or more laser beams with specific wavelengths output by the multi-wavelength laser are modulated by the modulators, the extra-cavity wavelength router routes them to the output port of the extra-cavity wavelength router corresponding to the certain port-selection semiconductor optical amplifier of the intra-cavity wavelength router; and
the output of the corresponding output port of the extra-cavity wavelength router includes one or more modulated laser signals with specific wavelengths, which are amplified by the signal gain semiconductor optical amplifier.

16. The multi-wavelength multi-port optical transmission router of claim 14, wherein by applying currents to a certain port-selection semiconductor optical amplifier and one or more wavelength-selection semiconductor optical amplifiers, the multi-wavelength laser outputs one or more specific wavelengths corresponding to the combination of the input and output ports in the intra-cavity wavelength router;
after one or more laser beams with specific wavelengths output by the multi-wavelength laser are modulated by the modulators, the extra-cavity wavelength router routes them to the output port of the extra-cavity wavelength router corresponding to the certain port-selection semiconductor optical amplifier of the intra-cavity wavelength router; and
the output of the corresponding output port of the extra-cavity wavelength router includes one or more modulated laser signals with specific wavelengths, which are amplified by the signal gain semiconductor optical amplifier.
